(19) United States
(12) Patent Application Publication
(10) Pub. No.: US 2015/0214204 A1
(43) Pub. Date: Jul. 30, 2015

(54) Electronic Device and Method for Fabricating an Electronic Device

(71) Applicant: Infineon Technologies AG, Neubiberg (DE)

(72) Inventor: Manfred Schindler, Regensburg (DE)

(21) Appl. No.: 14/165,769

(22) Filed: Jan. 28, 2014

(51) Int. Cl. H01L 25/18; H01L 23/31; H01L 23/00; H01L 25/00; H01L 23/495

(52) U.S. Cl. CPC H01L 25/18; H01L 25/50; H01L 23/49575; H01L 23/49562; H01L 24/83; H01L 23/3107; H01L 23/49568; H01L 2924/1304; H01L 2224/83815; H01L 2224/83851; H01L 2924/20101; H01L 2924/20102; H01L 2924/20103; H01L 2924/20104; H01L 2924/20105; H01L 2924/20106; H01L 2924/20107; H01L 2924/14; H01L 2924/1203; H01L 2924/2075; H01L 2924/20751; H01L 2924/20752; H01L 2224/32245

(57) ABSTRACT

A method for fabricating an electronic device includes simultaneously attaching a first and a second semiconductor chip to a carrier using a transfer means, wherein attaching the first semiconductor chip includes a first attaching method and attaching the second semiconductor chip includes a second attaching method different from the first attaching method.

### TECHNICAL FIELD

The present invention relates to an electronic device and a method for fabricating an electronic device.

### BACKGROUND

An electronic device may comprise a first semiconductor chip and a second semiconductor chip. Both of these semiconductor chips may be attached to a carrier. However, the first and second semiconductor chips maybe attached to the carrier using different attaching techniques which may lead to one or more of increased complexity of the fabrication process and increased cost of the electronic device. For these and other reasons there is a need for the present invention.

### BRIEF DESCRIPTION OF THE DRAWINGS

The accompanying drawings are included to provide a further understanding of embodiments and are incorporated in and constitute a part of this specification. The drawings illustrate embodiments and together with the description serve to explain principles of embodiments. Other embodiments and many of the intended advantages of embodiments will be readily appreciated as they become better understood by reference to the following detailed description. The elements of the drawings are not necessarily to scale relative to each other. Like reference numerals designate corresponding similar parts.

FIG. 1, which comprises FIG. 1A-1D, shows a cross section view of various stages of production of an embodiment of an electronic device.

FIG. 2, which comprises FIG. 2A-2C, shows a cross section view of various stages of production of a further embodiment of an electronic device.

FIG. 3A shows a cross section view of a further embodiment of an electronic device and FIG. 3B shows a top view of this embodiment.

FIG. 4 shows a top view of an example of a transfer means used in an embodiment of a method for fabricating an electronic device.

FIG. 5 shows a cross section view of a first and a second semiconductor chip, wherein the first and second chips show a deviation from an ideal orientation in an electronic device due to error margins during fabrication.

FIG. 6 shows a flow diagram of an embodiment of a method for fabricating an electronic device.

### DETAILED DESCRIPTION

In the following detailed description, reference is made to the accompanying drawings, which form a part thereof, and in which is shown by way of illustration specific embodiments in which the invention may be practiced. It may be evident, however, to one skilled in the art that one or more aspects of the embodiments may be practiced with a lesser degree of the specific details. In other instances, known structures and elements are shown in schematic form in order to facilitate describing one or more aspects of the embodiments. In this regard, directional terminology, such as “top”, “bottom”, “left”, “right”, “upper”, “lower” etc., is used with reference to the orientation of the Figure(s) being described. Because components of embodiments can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

In addition, while a particular feature or aspect of an embodiment may be disclosed with respect to only one of several implementations, such feature or aspect may be combined with one or more other features or aspects of the other implementations as may be desired and advantageous for any given or particular application, unless specifically noted otherwise or unless technically restricted. Furthermore, to the extent that the terms “include”, “have”, “with” or other variants thereof are used in either the detailed description or the claims, such terms are intended to be inclusive in a manner similar to the term “comprise”. The terms “coupled” and “connected”, along with derivatives thereof may be used. It should be understood that these terms may be used to indicate that two elements co-operate or interact with each other regardless whether they are in direct physical or electrical contact, or they are not in direct contact with each other; intervening elements or layers may be provided between the “bonded”, “attached”, or “connected” elements. Also, the term “exemplary” is merely meant as an example, rather than the best or optimal.

The semiconductor chip(s) described further below may be of different types, may be manufactured by different technologies and may include for example integrated electrical, electro-optical or electro-mechanical circuits and/or passives, logic integrated circuits, control circuits, microprocessors, memory devices, etc.

The embodiments of an electronic device and a method for fabricating an electronic device may use various types of semiconductor chips or circuits incorporated in the semiconductor chips, among them AC/DC or DC/DC converter circuits, power MOS transistors, diodes, power Schottky diodes, JFETs (Junction Gate Field Effect Transistors), power bipolar transistors, logic integrated circuits, analogue integrated circuits, mixed signal integrated circuits, sensor circuits, MEMS (Micro-Electro-Mechanical-Systems), power integrated circuits, chips with integrated passives, etc. The embodiments may also use semiconductor chips comprising MOS transistor structures or vertical transistor structures like, for example, IGBT (Insulated Gate Bipolar Transistor) structures or, in general, transistor structures in which at least one electrical contact pad is arranged on a first main face of the semiconductor chip and at least one other electrical contact pad is arranged on a second main face of the semiconductor chip opposite to the first main face of the semi-conductor chip. Moreover, the embodiments of insulation materials may, for example, be used for providing insulation layers in various types of enclosures and insulation for electrical circuits and components, and/or for providing insulation layers in various types of semiconductor chips or circuits incorporated in semiconductor chips, including the above mentioned semiconductor chips and circuits.

The semiconductor chip(s) can be manufactured from specific semiconductor material, for example Si, SiC, SiGe, GaAs, GaN, or from any other semiconductor material, and, furthermore, may contain one or more of inorganic and organic materials that are not semiconductors, such as for example insulators, plastics or metals.

The semiconductor chip(s) considered herein may be thin. In order to allow handling or manipulation of the semiconductor chip, e.g. handling/manipulation required for packaging, eWLP (embedded Wafer Level Packaging), or semiconductor device assembly, the semiconductor chip may form part of a composite chip. A composite chip may comprise the semiconductor chip and a reinforcing chip secured to the semiconductor chip. The reinforcing chip adds stability and/or strength to the composite chip to make it manageable.

The devices described below may include one or more semiconductor chips. Byway of example, one or more semiconductor power chips may be included. Further, one or more logic integrated circuits may be included in the devices. The logic integrated circuits may be configured to control the integrated circuits of other semiconductor chips, for example the integrated circuits of power semiconductor chips. The logic integrated circuits may be implemented in logic chips.

The semiconductor chip(s) may have contact pads (or electrodes) which allow electrical contact to be made with the integrated circuits included in the semiconductor chip(s). The electrodes may be arranged all at only one main face(s) of the semiconductor chip(s) or at both main faces of the semiconductor chip(s). They may include one or more electrode metal layers which are applied to the semiconductor material of the semiconductor chip(s). The electrode metal layers may be manufactured with any desired geometric shape and any desired material composition. For example, they may comprise or be made of a material selected of the group of Cu, Ni, NiSn, Au, Ag, Pt, Pd, an alloy of one or more of these metals, an electrically conducting organic material, or an electrically conducting semiconductor material.

The semiconductor chip(s) may be bonded to a carrier. The carrier may be a (permanent) device carrier used for packaging. The carrier may comprise or consist of any sort of material as, for example, ceramic or metallic material, copper or copper alloy or iron/nickel alloy. The carrier can be connected mechanically and electrically with one contact element of the semiconductor chip(s). The semiconductor chip(s) maybe connected to the carrier by one or more of re-flow soldering, vacuum soldering, diffusion soldering, or adhering by means of a conductive adhesive or a non-conductive adhesive. If diffusion soldering is used as the connection technology between the semiconductor chip(s) and the carrier, solder materials may be used which result in inter-metallic phases at the interface between the semiconductor and the carrier due to interface diffusion processes after the soldering process. In case of copper or iron/nickel carriers it may therefore be desirable to use solder materials comprising or consisting of AuSn, AgSn, CuSn, AgIn, AuIn or CuIn. Alternatively, if the semiconductor chip(s) are to be adhered to the carrier, conductive adhesives can be used. The adhesives can, for example, be based on epoxy resins or other suitable glues. The adhesives can be enriched with particles of gold, silver, nickel or copper to enhance their electrical conductivity.

The contact elements of the semiconductor chip(s) may comprise a diffusion barrier. The diffusion barrier prevents in case of diffusion soldering that the solder material diffuses from the carrier into the semiconductor chip(s). A thin titanium layer on the contact element may, for example, effect such a diffusion barrier.

Bonding the semiconductor chip(s) to the carrier may e.g. be done by soldering, gluing, or sintering. In case the semiconductor chip(s) are attached by soldering, a soft solder material or, in particular, a solder material capable of forming diffusion solder bonds may be used, for example a solder material comprising one or more metal materials selected from the group of Sn, SnAg, SnAu, SnCu, In, InAg, InCu and InAu.

The semiconductor chip(s) may be covered with an encapsulation material in order to be embedded in an encapsulant (artificial wafer) for eWLP processing or after being bonded to a device carrier (substrate). The encapsulation material may be electrically insulating. The encapsulation material may comprise or be made of any appropriate plastic or polymer material such as, e.g., a duroplastic, thermoplastic or thermosetting material or laminate (prepreg), and may e.g. contain filler materials. Various techniques may be employed to encapsulate the semiconductor chip(s) with the encapsulation material, for example compression molding, injection molding, powder molding, liquid molding or lamination. Heat and/or pressure may be used to apply the encapsulation material.

In several embodiments layers or layer stacks are applied to one another or materials are applied or deposited onto layers. It should be appreciated that any such terms as “applied” or “deposited” are meant to cover literally all kinds and techniques of applying layers onto each other. In particular, they are meant to cover techniques in which layers are applied at once as a whole like, for example, laminating techniques as well as techniques in which layers are deposited in a sequential manner like, for example, sputtering, plating, molding, CVD, etc.

In the following description and claims different embodiments of a method for fabricating an electronic device are described as a particular sequence of processes or measures, in particular in a flow diagram. It is to be noted that the embodiments should not be limited to the particular sequence described. Particular ones or all of different processes or measures can also be conducted simultaneously or in any other useful and appropriate sequence.

An embodiment of an electronic device may comprise a first semiconductor chip and a second semiconductor chip, each attached to a carrier. The carrier may comprise a leadframe. However, the first and the second semiconductor chips may be attached to the carrier using different die attach processes. In particular, the first semiconductor chip may be attached to the carrier using a solder process. According to an embodiment, a diffusion solder process may be used. The second semiconductor chip however may be attached to the carrier using a gluing process using an adhesive. According to another embodiment, attaching the second semiconductor chip comprises a sintering process.

The first and second semiconductor chips may be individually electrically connected to the carrier or may be individually electrically insulated from the carrier. For example, a conductive glue may be used to electrically connect the second semiconductor chip to the carrier. Alternatively, an insulation layer may be used to provide electrical insulation.

The first and second semiconductor chips may each comprise a first main face, a second main face opposite the first main face and side faces connecting the first and second main face. The semiconductor chips may be attached to the carrier such that the second main faces face the carrier and the first main faces are located in the same plane, that is they are coplanar. Coplanarity of the first main faces of the first and second semiconductor chips may be very good. That means, a deviance of a first plane spanned by the first main face of the first semiconductor chip from a second plane spanned by the first main face of the second semiconductor chip may be less than 40 μm, or less than 30 μm, or less than 25 μm, or even less than 20 μm. Furthermore, each of the first and second plane may enclose an angle with an ideal plane of orientation, wherein each angle may be less than 2°, or less than 1°, or less than 0.5° or may even be essentially zero, meaning that the first and second plane are essentially parallel.

The first and second semiconductor chips may exhibit a difference in thickness measured from the first main face to the second main face. The difference in thickness may be large and may in particular be larger than 5 μm, larger than 10 μm, larger than 20 μm, larger than 30 μm, or even larger than 40 μm.

In order for two semiconductor chips of different thickness in an electronic device to have coplanar first main faces, a carrier surface may comprise a cavity designed for accommodating one of the semiconductor chips. For example, the second semiconductor chip may be accommodated in the cavity.

As stated above the second semiconductor chip comprised in an electronic device may be attached to the carrier using a glue. According to an embodiment the glue may completely cover the second main face and all side faces of the second semiconductor chip from the second main face up to the first main face. Such a thorough coverage with glue may improve heat dissipation away from the second semiconductor chip. For example, conductive glue may have 23 times the heat conductance of epoxy. Furthermore, the glue may comprise an upper face coplanar with the first main face of the second semiconductor chip.

According to an embodiment an electronic device may comprise at least a third semiconductor chip. The first main face(s) of the one or more further semiconductor chip(s) may be coplanar with the main faces of the first and second semiconductor chips.

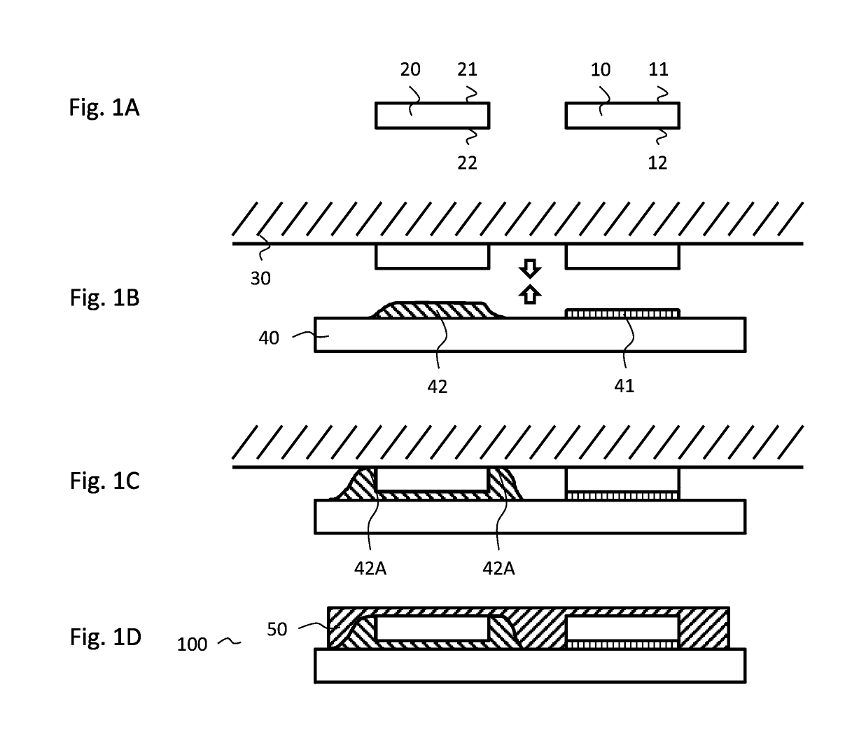

With respect to FIG. 1A-1D various stages of production of an electronic device 100 are shown. FIG. 1A shows a first semiconductor chip 10 and a second semiconductor chip 20. The first and second semiconductor chips 10, 20 comprise first main faces 11, 21 and second main faces 12, 22 opposite the first main faces. The first and second semiconductor chips may comprise one or more electrodes on their first and second main faces. Each semiconductor chip may solely comprise electrodes on one of its main faces or may comprise electrodes on both main faces. First and second semiconductor chips 10, 20 maybe provided in singulated form or they may be still connected to a wafer or a reconstituted wafer. Each one of first and second semiconductor chips 10, 20 may have a horizontal transistor structure or a vertical transistor structure.

With respect to FIG. 1B a transfer means 30 is shown. The first and second semiconductor chips 10, 20 are attached to the transfer means 30. The transfer means 30 may comprise an adhesive foil whereupon the semiconductor chips are adhered to with their first main faces 11, 21.

FIG. 1B further shows a carrier 40 to which the semiconductor chips 10, 20 are to be attached to. Attaching the first semiconductor chip 10 may comprise diffusion soldering and attaching the second semiconductor chip 20 may comprise gluing. For example, a diffusion solder deposit 41 and a glue deposit 42 may be provided.

Then the semiconductor chips 10, 20 and the carrier 40 may be brought into contact such that the second main face 12 of the first semiconductor chip 10 contacts the diffusion solder deposit 41 and the second main face 22 of the second semiconductor chip 20 contacts the glue deposit 42. Note that during the attachment process the semiconductor chips 10, 20 are still connected to the transfer means 30. Furthermore, attaching the semiconductor chips 10, 20 may be done simultaneously in a parallel process.

Attaching may comprise applying one or more of heat and pressure to the diffusion solder deposit 41 and the glue deposit 42. As shown in FIG. 1C, the heat or the pressure or a combination of heat and pressure may cause the glue to completely cover the second main face 22 and all side faces of the second semiconductor chip 20. However, since first main face 21 of semiconductor chip 20 is still completely covered by transfer means 30 the glue cannot contaminate any part of it. Instead, due to the presence of transfer means 30 during attachment an upper face 42A of the glue may form which is coplanar with the first main face 21. The presence of the transfer means may give mechanical support to the chips 10, 20 during the attachment process and curing of the solder 41 and glue 42 and fix the chips in place. Thus, because the first and second semiconductor chips still adhere to the transfer means during the attachment process, a glue deformation stress during glue curing is countered. This may allow for an improved coplanarity of the chips 10, 20 compared to a serial die attach process.

Diffusion soldering of the first semiconductor chip 10 may comprise Advanced Diffusion Soldering (ADS). In particular, ADS may require heat of no more than 260° C., or even no more than 250° C. due to the use of low temperature solder. Standard diffusion soldering may require higher or even much higher temperatures which may not be suitable for gluing. Due the comparably low temperature requirements of ADS diffusion soldering of the first semiconductor chip 10 and gluing of the second semiconductor chip 20 to the carrier 40 respectively can be carried out in one simultaneous heating step.

After hardening of the solder bond and the glue the transfer means 30 may be removed from the first main faces 11, 21. Transfer means 30 may for example comprise a thermo release foil which loses its adhesive properties upon a temperature change. Furthermore, transfer means 30 may for example comprise a UV foil which changes its adhesive properties under UV illumination. Furthermore, transfer means 30 may comprise a plate, for example a glass plate. The plate may be covered with an adhesion means, like a glue or an adhesive tape, designed to adhere to semiconductor chips. Transfer means 30 may further comprise a metal plate. The metal plate may be designed to homogeneously apply a temperature to semiconductor chips adhered to the transfer means. The metal plate may further be designed to stabilize an adhesive foil and allow for a homogeneously pressing adhered semiconductor chips onto a carrier during an attachment process. Removing the adhesive foil from the semiconductor chips may comprise applying mechanical force to it or it may simply comprise peeling off the adhesive foil from the first main faces 11, 21.

With respect to FIG. 1D an embodiment of an electronic device 100 after removal of the transfer means 30 is shown. Electronic device 100 comprises first semiconductor chip 10 soldered to carrier 40 and second semiconductor chip 20 glued to carrier 40. Electronic device 100 may further comprise an encapsulant 50 configured to encapsulate the first and second semiconductor chips 10, 20. Note that the chips 10, 20 need not necessarily be encapsulated together in a single encapsulant but may also be encapsulated individually according to an embodiment.

In FIG. 1A-1D first and second semiconductor chips 10, 20 were shown to exhibit the same thickness, measured from the first main face to the second main face. However, this needs not necessarily be the case as the method for fabricating an electronic device can also be used to handle first and second semiconductor chips exhibiting a difference in thickness as already mentioned further above. However, due to the presence of the transfer means during chip attachment to the carrier, the first main faces of the chips need to be coplanar.

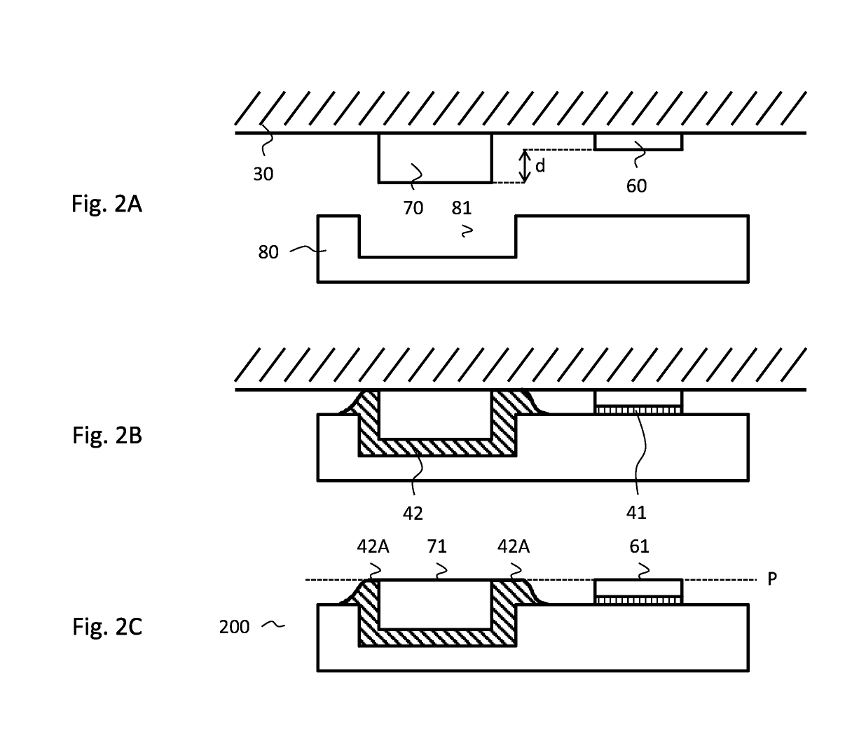

With respect to FIG. 2A a first semiconductor chip 60 and a second semiconductor chip 70 are shown. Semiconductor chips 60, 70 are attached to transfer means 30. Second semiconductor chip 70 is thicker than first semiconductor chip 60 by a margin d. d may be more than 5 μm, more than 10 μm, more than 20 μm, more than 30 μm, more than 50 μm and even more than 100 μm. According to an embodiment, first semiconductor chip 60 may be a thinned chip and second semiconductor chip 70 may be a non-thinned chip. For example, second chip 70 may have a thickness of 100 μm or more, 150 μm or more, or even 200 μm or more.

FIG. 2A further shows a carrier 80 comprising a cavity 81 configured to hold the second semiconductor chip 70. Due to the cavity the first main face of the thicker chip 70 may be coplanar with the first main face of the thinner chip 60 during and after chip attachment.

FIG. 2B shows the semiconductor chips 60, 70 attached to the carrier 80. The first main faces of the semiconductor chips 60, 70 are still connected to the transfer means 30. First semiconductor chip 60 is attached to the carrier using a solder and second semiconductor chip 70 is attached using a glue, which may be a conductive glue in some embodiments. The description of the attachment process given further above with respect to FIG. 1C can also be applied to FIG. 2B and is therefore not repeated here.

FIG. 2C shows an electronic device 200 after removal of the transfer means 30. Due to the presence of the transfer means 30 during the attachment step, the first main faces 61, 71 of chips 60, 70 and the upper face 42A of the glue are located in plane of coplanarity P. Electronic device 200 may further comprise an encapsulant configured to encapsulate chips 60, 70 and electrical connection elements configured to connect electrodes on the chips 60, 70 to the outside of the electronic device 200.

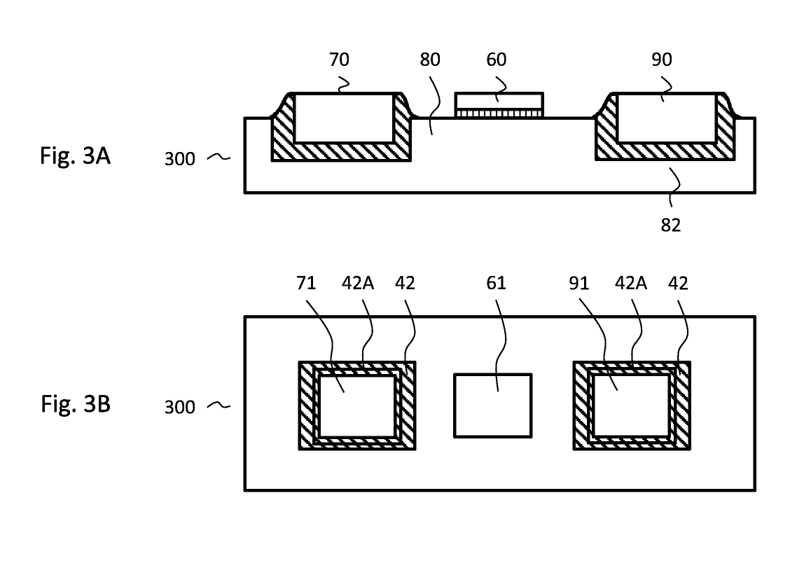

With respect to FIG. 3A an embodiment of an electronic device 300 is shown. Electronic device 300 comprises essentially similar parts as electronic devices 100, 200 like first and second semiconductor chips 60, 70 and carrier 80. However, electronic device 300 further comprises a third semiconductor chip 90. According to an embodiment semiconductor chip 90 may be attached to carrier 80 analogously to second semiconductor chip 70, that is using a glue. Third semiconductor chip 90 may be located in a second cavity 82.

According to a further embodiment not shown here third semiconductor chip 90 may be attached to carrier 80 using a solder analogously to first semiconductor chip 60. In any case, first main faces of all semiconductor chips 60, 70, 90 are coplanar due to them being connected to transfer means 30 during the attachment process.

With respect to FIG. 3B a top view of electronic device 300 is shown. As can be seen, glue 42 may completely surround semiconductor chips 70, 90 such that all side faces are completely covered and an upper face 42A of glue 42 is coplanar with first main faces 61, 71, 91.

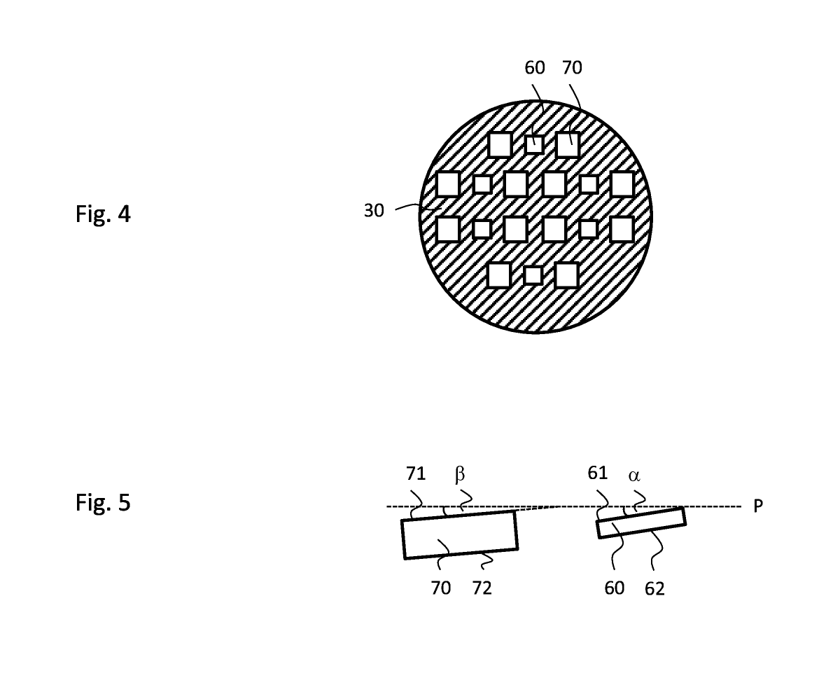

With respect to FIG. 4 a top view of an example of transfer means 30 is shown. Transfer means 30 may comprise a transfer foil whereupon first semiconductor chip 60 and second semiconductor chip 70 adhere to. As already mentioned, the method for fabricating an electronic device may be used in a batch process such that multiple electronic devices are fabricated in parallel. Therefore, a multitude of first semiconductor chips 60 adhered to transfer means 30 and a multitude of second semiconductor chips 70 adhered to transfer means 30 may be provided. The chips 60, 70 may be arranged in a defined pattern suitable for a batch process for fabricating a multitude of electronic devices in parallel. For example, first and second semiconductor chips to be attached to a leadframe strip are mounted on a batch die attach foil.

With respect to FIG. 5 semiconductor chips 60, 70 of an electronic device like the electronic devices 100, 200, or 300 are shown. Not depicted is a carrier to which the chips 60, 70 are attached to, such that second main faces 62, 72 face the carrier. Due to some margins in the precision of the attachment process the chips 60, 70 may each be tilted by an angle alpha and beta, respectively, with regard to an ideal plane of orientation P. The ideal plane of orientation may for example be defined by a surface of a carrier or by a surface of a transfer means to which the chips 60, 70 adhere.

For the method of fabricating an electronic device using a transfer means 30 this tilt may be smaller than it would be possible when using a serial process like a pick and place process to attach the chips 60, 70 to a carrier. In particular, the angles alpha, beta may be smaller than 2°, smaller than 1°, smaller than 0.5°, smaller than 0.1° and may even be essentially zero.

Furthermore, due to the presence of the transfer means during the attachment of chips 60, 70 on the carrier the first main faces 61, 71 may exhibit a height deviation from plane P which may be less than 40 μm, or less than 30 μm, or less than 25 μm, or even less than 20 μm and may even be essentially zero.

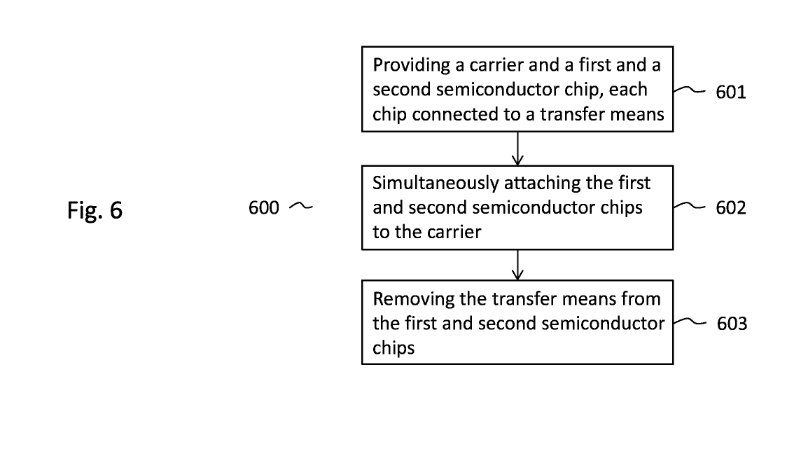

With respect to FIG. 6 a flow chart of a method 600 for fabricating an electronic device is shown. The method may comprise a first step 601, wherein first step 601 comprises providing a first and a second semiconductor chip connected to a transfer means. First step 601 may further comprise providing a carrier.

Method 600 further comprises a second step 602 comprising simultaneously attaching the first and second semiconductor chips to the carrier. Attaching the first semiconductor chip may comprise soldering and attaching the second semiconductor chip may comprise gluing. Soldering and gluing may comprise applying heat in a single process step to both a solder reservoir and a glue reservoir. Such a simultaneous soldering and gluing step may be highly cost efficient compared to a serial process. The costs of a serial process may be a factor two higher than the costs of the parallel attachment process of method 600.

Method 600 further comprises a third step 603 comprising removing the transfer means from the first and second semiconductor chips. According to an embodiment of method 600 the transfer means is removed after the solder and the glue applied in step 602 are cured and the first and second semiconductor chips are firmly attached to the carrier.

Although the present invention and its advantages have been described in detail, it should be understood that various changes, substitutions and alterations can be made herein without departing from the spirit and scope of the invention as defined by the appended claims.

Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

While the invention has been illustrated and described with respect to one or more implementations, alterations and/or modifications may be made to the illustrated examples without departing from the spirit and scope of the appended claims. In particular regard to the various functions performed by the above described components or structures (assemblies, devices, circuits, systems, etc.), the terms (including a reference to a “means”) used to describe such components are intended to correspond, unless otherwise indicated, to any component or structure which performs the specified function of the described component (e.g., that is functionally equivalent), even though not structurally equivalent to the disclosed structure which performs the function in the herein illustrated exemplary implementations of the invention.

What is claimed is:

1. A method for fabricating an electronic device, the method comprising:
providing a first semiconductor chip and a second semiconductor chip, both connected to a transfer means;
providing a carrier;
simultaneously attaching the first and second semiconductor chips to the carrier; and
wherein attaching the first semiconductor chip comprises soldering and attaching the second semiconductor chip comprises gluing.

2. The method of claim 1, wherein the transfer means comprises an adhesive foil.

3. The method of claim 1, wherein the first and second semiconductor chips are attached to the carrier such that second main faces of the first and second semiconductor chips face the carrier and first main faces of the first and second semiconductor chips opposite the second main faces are coplanar.

4. The method of claim 1, wherein the method is a batch method configured for fabricating multiple semiconductor devices in parallel.

5. The method of claim 1, wherein attaching the first and second semiconductor chips to the carrier comprises applying heat of no more than 260° C.

6. The method of claim 1, wherein the second semiconductor chip comprises a first main face and a second main face opposite the first main face;
wherein the second semiconductor chip is oriented such that its second main face faces the carrier; and
wherein during gluing a glue is applied such that the glue comprises an upper face coplanar with the first main face of the second semiconductor chip.

7. The method of claim 2, further comprising:
removing the adhesive foil.

8. The method of claim 1, wherein the carrier comprises a cavity configured to hold the second semiconductor chip.

9. The method of claim 1, wherein the carrier comprises a leadframe.

10. The method of claim 1, wherein the first and second semiconductor chips comprise one or more of an integrated circuit chip, a power chip and a diode.

11. An electronic device, comprising:
a first semiconductor chip and a second semiconductor chip, the first and second semiconductor chips each comprising a first main face and a second main face opposite the first main face; and
a carrier,
wherein the first semiconductor chip is attached to the carrier using a solder such that its second main face faces the carrier,
wherein the second semiconductor chip is attached to the carrier using a glue such that its second main face faces the carrier,
wherein the glue comprises an upper face coplanar with the first main face of the second semiconductor chip.

12. The electronic device of claim 11, wherein the first main face of the first semiconductor chip is coplanar with the first main face of the second semiconductor chip such that an error in the coplanarity is no greater than 20 μm.

13. The electronic device of claim 11, further comprising a third semiconductor chip.

14. The electronic device of claim 11, further comprising an encapsulant configured to encapsulate the first and second semiconductor chips.

15. The electronic device of claim 14, wherein the encapsulant comprises one or more of a mold and a laminate.

16. The electronic device of claim 11, wherein the glue is configured to dissipate heat away from the second semiconductor chip.

17. The electronic device of claim 11, wherein the second semiconductor chip is electrically connected to the carrier.

18. An electronic device, comprising:
a first semiconductor chip and a second semiconductor chip, each semiconductor chip comprising a first main face and a second main face opposite the first main face; and
a carrier,
wherein the first semiconductor chip is attached to the carrier using a solder such that its second main face faces the carrier,
wherein the second semiconductor chip is attached to the carrier using a glue such that its second main face faces the carrier,
wherein a height difference between a first plane spanned by the first main face of the first semiconductor chip and a second plane spanned by the first main face of the second semiconductor chip is no greater than 20 μm.

19. The electronic device of claim 18, wherein the first and second semiconductor chips show a difference in thickness of more than 5 μm.

20. The electronic device of claim 18, wherein one of the first and second semiconductor chips has a horizontal transistor structure and the other semiconductor chip has a vertical transistor structure.
